(19) United States
(12) Patent Application Publication
(10) Pub. No.: US 2026/0227441 A1
(43) Pub. Date: Aug. 6, 2026

(54) HARDWARE-BASED PERIODIC SELF-TESTING OF SAFETY MECHANISMS

(71) Applicant: QUALCOMM Incorporated, San Diego, CA (US)

(72) Inventors: Sateeshkumar INJARAPU, Bangalore (IN); Amit DUGGAL, Bangalore (IN); Nitin JAISWAL, Bangalore (IN); Robert BATEMAN, San Diego, CA (US)

(21) Appl. No.: 19/045,461

(22) Filed: Feb. 4, 2025

(51) Int. Cl. G01R 31/3181

(52) U.S. Cl. CPC G01R 31/31813

(57) ABSTRACT

A method for hardware-based periodic self-testing of safety mechanisms includes generating a test pattern after data processing has initiated in at least one block of a processor. The test pattern is provided to a safety mechanism. The safety mechanism generates a syndrome based on the test pattern. A fault in the safety mechanism is determined based on the syndrome.

### FIELD OF THE DISCLOSURE

Aspects of the present disclosure generally relate to computing devices, and more particularly to hardware-based periodic self-testing of safety mechanisms.

### BACKGROUND

Functional safety is an aspect of computer system design, particularly in automotive, aerospace, industrial automation, and medical device contexts. Functional safety includes implementing mechanisms to increase the likelihood that a system behaves predictably and safely in the presence of faults. Functional safety standards provide frameworks for the development, validation, and verification of safety systems. These standards include rigorous risk assessment, hazard analysis, and the use of redundant and diverse design techniques to mitigate potential hazards. Strategies for implementing functional safety involve built-in self-tests (BISTs), safety integrity levels (SILs), fail-safe and fail-operational modes, and comprehensive safety case documentation to demonstrate that safety specifications are satisfied throughout the product lifecycle.

In the automotive industry, vehicles are rated via an Automotive Safety Integrity Level (ASIL) rating system. ASIL ratings, ranging from ASIL-A to ASIL-D, categorize the severity of potential hazards and the rigor specified to mitigate the hazards. ASIL-A represents the lowest safety integrity level and is awarded to systems implementing fewer safety measures, while ASIL-D signifies the highest safety integrity level and is awarded to systems implementing more stringent safety protocols. These ratings guide automotive development, validation, and verification processes to increase the likelihood that automotive systems can operate safely, even in the presence of faults. The ASIL framework encompasses risk assessment, hazard analysis, and the implementation of redundant and diverse safety mechanisms to prevent or mitigate failures. Hardware enabled BIST is one technique for ensuring safety specifications are satisfied.

A conventional power-on logic built-in self-test (BIST) may detect faults in the safety mechanism, but may only be able to detect such faults during power-up time, which limits the identification of faults that occur during the data processing.

### SUMMARY

Various aspects of the present disclosure are directed to an apparatus. The apparatus has at least one memory, safety mechanism for at least one block of a processor and logic for testing the safety mechanism. The logic is configured to generate a test pattern after data processing has initiated in at least one block of a processor. The logic is also configured to provide the test pattern to a safety mechanism. The safety mechanism generates a syndrome based on the test pattern. The logic is further configured to determine a fault in the safety mechanism based on the syndrome.

In some aspects of the present disclosure, a method includes generating a test pattern after data processing has initiated in at least one block of a processor. The method also includes providing the test pattern to a safety mechanism. The safety mechanism generates a syndrome based on the test pattern. The method further includes determining a fault in the safety mechanism based on the syndrome.

Various aspects of the present disclosure are directed to an apparatus. The apparatus includes means for generating a test pattern after data processing has initiated in at least one block of a processor. The apparatus also includes means for providing the test pattern to a safety mechanism. The safety mechanism generates a syndrome based on the test pattern. The apparatus further includes means for determining a fault in the safety mechanism based on the syndrome.

Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings in which like reference characters identify correspondingly throughout.

FIG. 1 illustrates an example implementation of a system-on-a-chip (SOC), in accordance with various aspects of the present disclosure.

FIG. 2 illustrates an example of an automobile including systems that may be adapted, configured, or operated, in accordance with various aspects of the present disclosure.

FIG. 3 is a block diagram illustrating an Automotive Safety Integrity Level (ASIL) data path.

FIG. 4 is a block diagram illustrating an example architecture for hardware-based periodic self-testing of safety mechanisms, in accordance with various aspects of the present disclosure.

FIG. 5 is a diagram illustrating an example timeline for periodic self-testing of safety mechanisms, in accordance with various aspects of the present disclosure.

FIG. 6 is a flow diagram illustrating an example process for hardware-based periodic self-testing of safety mechanisms, in accordance with various aspects of the present disclosure.

FIG. 7 is a flow chart illustrating an example process performed, for example, by hardware logic such as a pattern generator, in accordance with various aspects of the present disclosure.

FIG. 8 is a block diagram illustrating a design workstation used for circuit, layout, and logic design of built-in self-test (BIST) components, in accordance with various aspects of the present disclosure.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

Based on the teachings, one skilled in the art should appreciate that the scope of the disclosure is intended to cover any aspect of the disclosure, whether implemented independently of or combined with any other aspect of the disclosure. For example, an apparatus may be implemented or a method may be practiced using any number of the aspects set forth. In addition, the scope of the disclosure is intended to cover such an apparatus or method practiced using other structure, functionality, or structure and functionality in addition to or other than the various aspects of the disclosure set forth. It should be understood that any aspect of the disclosure disclosed may be embodied by one or more elements of a claim.

The word “exemplary” is used to mean “serving as an example, instance, or illustration.” Any aspect described as “exemplary” is not necessarily to be construed as preferred or advantageous over other aspects.

Although particular aspects are described, many variations and permutations of these aspects fall within the scope of the disclosure. Although some benefits and advantages of the preferred aspects are mentioned, the scope of the disclosure is not intended to be limited to particular benefits, uses or objectives. Rather, aspects of the disclosure are intended to be broadly applicable to different technologies, system configurations, networks, and protocols, some of which are illustrated by way of example in the figures and in the following description of the preferred aspects. The detailed description and drawings are merely illustrative of the disclosure rather than limiting, the scope of the disclosure being defined by the appended claims and equivalents thereof.

Several aspects of functional safety management will now be presented with reference to various apparatuses and techniques. These apparatuses and techniques will be described in the following detailed description and illustrated in the accompanying drawings by various blocks, modules, components, circuits, steps, processes, algorithms, and/or the like (collectively referred to as “elements”). These elements may be implemented using hardware, software, or combinations thereof. Whether such elements are implemented as hardware or software depends upon the particular application and design constraints imposed on the overall system.

As described, automotive systems executing safety critical applications or functions are rated with an Automotive Safety Integrity Level (ASIL) rating system. The ASILs may be defined in a specific safety standard, such as the International Organization for Standardization (ISO) 26262. For example, the ASILs may provide a risk classification scheme for certain electrical and electronic systems of road vehicles. ISO 26262 provides four ASILs including ASIL-A, ASIL-B, ASIL-C, and ASIL-D. ASIL-D is the highest classification and corresponds to the highest level of safety measures for avoiding an unreasonable residual risk, and ASIL-A is the lowest classification and corresponds to the lowest level of safety measures. ASIL ratings, ranging from ASIL-A (lowest) to ASIL-D (highest), categorize the severity of potential hazards and the rigor specified to mitigate the hazards.

Development of advanced driver assistance systems (ADASs) and automated driving systems (ADSs), as well as associated safety and mission critical applications in the automotive industry, have prompted many safety critical applications to specify ASIL-D safety ratings. As a result, vehicle and chip manufacturers have developed conventional approaches to develop and manufacture ASIL-D hardware. In one approach, a system-on-a-chip (SOC) and memory elements include several components along an inline data path. The components are each individually designed and manufactured to satisfy ASIL specifications (e.g., ASIL-D or ASIL-C specifications), enabling the entire data path to reach ASIL-D or ASIL-C status. Hardware enabled built-in self-test (BIST) is one technique for ensuring safety specifications are satisfied.

Critical safety systems and the central processing unit (CPU) cluster may be tested upon boot-up to ensure compliance with the safety specifications. Each of these components may be subject to hardware enabled BIST when powering on and powering off the vehicle before operating the vehicle in the field.

BIST is a technique to test the functionality of integrated circuits (ICs) by embedding test circuitry within an IC to allow the IC to periodically test its own operation. Logic BIST (LBIST) uses a pseudo-random pattern generator to generate test patterns that are applied to internal scan chains of the circuit under test. The response to the test patterns input to the circuit under test is compressed into a signature. Comparisons to a multiple input signature register (MISR) pattern determine whether the signature is correct, indicating the circuit under test is properly functioning.

However, a conventional power-on logic built-in self-test (BIST) may detect faults in the safety mechanism, but only during power-up time, which limits the identification of faults that occur during the data processing.

Other safety mechanisms may comprise additional logic implemented to protect the critical safety logic. One safety mechanism involves an error correcting code (ECC) for memories to detect double errors and correct single errors. If a fault occurs in the safety critical logic, the safety mechanism may detect or correct the faults. However, if there is a fault in the safety mechanism implementation itself, the safety mechanism may produce false positive detections or may miss detecting actual faults.

To address these and other problems, aspects of the present disclosure are directed to hardware-based periodic self-testing of the safety mechanism. In various aspects, the disclosed approach may periodically test and detect the faults during data processing. The periodic testing may be performed by software, using a software test library (STL), or using hardware, for example. However, periodic testing by a STL may be time consuming and intrusive to the functional path. Thus, implementation of the testing using hardware may be more efficient.

In accordance with aspects of the present disclosure, a hardware-based periodic BIST architecture may periodically check for faults in an ECC safety mechanism when the respective block/processer is in an IDLE state but not powered-off. Accordingly, the described approach may beneficially provide a mechanism that is non-intrusive, non-software dependent, and may cover the intended logic during power-up time and during data processing. The described approach may be employed in automotive applications and other mission critical applications.

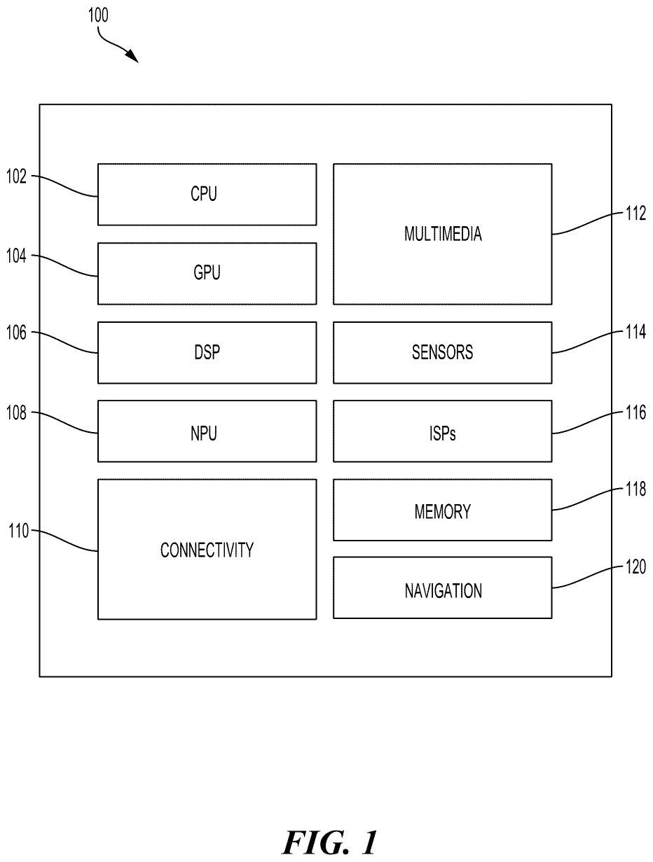

FIG. 1 illustrates an example implementation of a system-on-a-chip (SOC) 100, which may include a central processing unit (CPU) 102 or a multi-core CPU configured for periodic hardware-based self-testing for safety mechanisms. Variables (e.g., neural signals and synaptic weights), system parameters associated with a computational device (e.g., neural network with weights), delays, frequency bin information, and task information may be stored in a memory block associated with a neural processing unit (NPU) 108, in a memory block associated with a CPU 102, in a memory block associated with a graphics processing unit (GPU) 104, in a memory block associated with a digital signal processor (DSP) 106, in a memory block 118, or may be distributed across multiple blocks. Instructions executed at the CPU 102 may be loaded from a program memory associated with the CPU 102 or may be loaded from a memory block 118.

The SOC 100 may also include additional processing blocks tailored to specific functions, such as a GPU 104, a DSP 106, a connectivity block 110, which may include fifth generation (5G) connectivity, fourth generation long term evolution (4G LTE) connectivity, Wi-Fi connectivity, USB connectivity, Bluetooth connectivity, and the like, and a multimedia processor 112 that may, for example, detect and recognize gestures. In one implementation, the NPU 108 is implemented in the CPU 102, DSP 106, and/or GPU 104. The SOC 100 may also include a sensor processor 114, image signal processors (ISPs) 116, and/or navigation module 120, which may include a global positioning system.

The SOC 100 may be based on any architecture, such as a complex instruction set (CISC) architecture, an ARM, RISC-V (RISC-five), or any reduced instruction set computing (RISC) architecture. In aspects of the present disclosure, the instructions loaded into the CPU 102 may include code to generate a test pattern after data processing has initiated in at least one block of a processor. The instructions loaded into the CPU 102 may also include code to provide the test pattern to a safety mechanism. The safety mechanism generates a syndrome based on the test pattern. The instructions loaded into the CPU 102 may further include code to determine a fault in the safety mechanism based on the syndrome.

According to aspects of the present disclosure, an apparatus includes a LBIST mechanism. The apparatus may include means for generating a test pattern, means for providing the test pattern to a safety mechanism, and means for determining a fault in the safety mechanism.

For example, the means for may be any of the CPU 102, clock gating logic 402 and a pattern generator 404, a flip flop 406 and multiplexors (MUXs) 408, 416, flip flop 422 and the inverter 424. For example, the means for generating a test pattern may be any of the pattern generator 404, flip flop 422 and/or the inverter 424. For example, the means for providing the test pattern to a safety mechanism may be any of the pattern generator 404, the multiplexors (MUXs) 408, and/or inverter 424. For example, the means for determining a fault in the safety mechanism may be any of pattern generator 404, MUX 408, 416, the safety mechanism 410, and/or ECC memory 414.

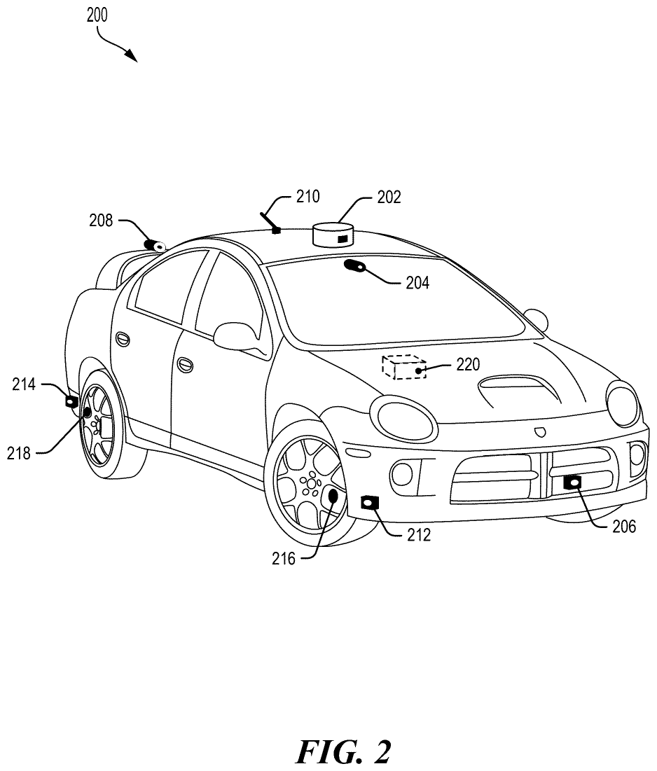

FIG. 2 illustrates an example of an automobile including systems that may be adapted, configured, or operated in accordance with various aspects of this disclosure. The automobile 200 may be equipped with multiple imaging or sensing devices including, for example, cameras 202, 204, 206, 208, 212, 214, and sensors 216, 218. The automobile 200 may include sensors such as tire pressure or braking sensors as the sensors 216, 218. The automobile 200 may also include one or more antennas 210 for radio frequency reception, wireless communication and/or radio navigation using a position location system, such as a global positioning system (GPS). A central controller 220 may be coupled to each of the cameras 202, 204, 206, 208, 212, 214, sensors 216, 218 and antennas 210. The central controller 220 may configure and manage automated systems and/or driver assistance systems. In some implementations, the central controller 220 may be configured to operate as an engine control unit that manages the operation and performance of the engine, motor, motors, or other power systems in the automobile 200. In some instances, the central controller 220 may include an SOC, such as the SOC 100.

Robust data communication links are specified to support the large number of cameras deployed within the automobile 200. In some examples, 20-30 cameras may be deployed to support automation and driver assistance systems. Each camera may be capable of generating data at a rate of between 1-10 gigabits per second (GBps) resulting in aggregate data rates of up to 300 GBps.

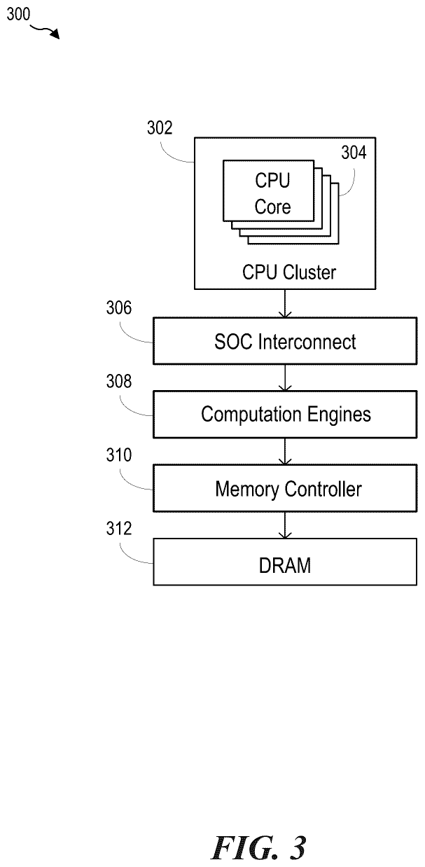

FIG. 3 is a block diagram illustrating an automotive data path 300. As shown, the data path 300 includes a CPU cluster 302. Although a single CPU cluster 302 is depicted for ease of explanation, the present disclosure is not so limited. The CPU cluster 302 includes a set of CPU cores 304 that work concurrently or in parallel to perform computational tasks via workloads distributed across the set of CPU cores 304. The set of CPU cores 304 are respectively interconnected such that each core may perform a portion of a task. Portions of a task may be assigned to each core of the CPU cores 304 by a scheduler (not illustrated) hosted by the CPU cluster 302. The CPU cluster 302 is coupled to an SOC interconnect 306.

The SOC interconnect 306 links various upstream components, such as the CPU cluster 302 and cache (not illustrated) to various downstream components. Additionally, the SOC interconnect 306 facilitates on-chip communications and transaction handling between the upstream components and downstream components on the data path 300. The SOC interconnect 306 is coupled to computation engines 308. The computation engines 308 represent one or more logic structures on the data path 300 that are downstream from the SOC interconnect 306.

The computation engines 308 may include functionally complex, area intensive logic structures on the path to dynamic random access memory (DRAM) in an SOC. For example, the computation engines 308 may include compression engines, encryption engines, a last-level cache, and other computational or memory structures. Compression engines apply compression techniques to reduce the data footprint of data packets transmitted on the data path 300, thus reducing bandwidth specified to transmit the data packets. Encryption engines implement cryptographic techniques to encrypt data packets. A last-level cache serves as high-capacity, low-latency memory storage for upstream components such as the CPU cluster 302. The computation engines 308 are coupled to a memory controller 310.

The memory controller 310 manages data flow between DRAM 312 and upstream components on the data path 300, such as the CPU cluster 302. The memory controller 310 coordinates memory access requests from the upstream components to reduce memory bandwidth and latency. The DRAM 312, coupled to the memory controller 310, serves as the primary volatile storage for the data path 300, providing memory space for stored information. While smaller data packets and data packets specifying low access latency may be stored in a cache within the data path 300, larger data packets and data packets specifying higher access latency may instead by stored in the DRAM 312 by the memory controller 310.

In FIG. 3, each of the components in the data path 300 may be rated as conforming to the highest safety integrity level, e.g., ASIL-D. For instance, ASIL-D may specify strict path protection across complex structures, such as the computation engines 308, memory controller 310, and DRAM 312. Similarly, other safety levels, such as ASIL-C, may also be associated with components in the data path 300. Safety systems, the CPU cluster 302, and other critical systems may be tested upon boot-up to ensure compliance with the safety specifications. Each of these components in the data path 300 may be subject to hardware enabled built-in self-test (BIST) when powering on and powering off the vehicle before operating the vehicle in the field.

BIST is a technique to test functionality of ICs by embedding test circuitry within an IC to allow the IC to periodically test its own operation. Logic BIST (LBIST) uses a pseudo-random pattern generator to generate test patterns that are applied to internal scan chains of the circuit under test. The response to the test patterns input to the circuit under test is compressed into a signature. Comparisons to a multiple input signature register (MISR) pattern determine whether the signature is correct, indicating the circuit under test is properly functioning.

The MISR patterns are stored on-chip in read only memory (ROM). The ROM images, however, are frozen during chip design (e.g., base tape out (BTO)), and thus, changes in the patterns after chip design are cost prohibitive, preventing updates to the ROM image on silicon. It would be desirable to be able to update the MISR patterns after tape out, without impacting boot-up performance (e.g., speed).

As described, aspects of the present disclosure are directed to a hardware-based periodic self-testing of the safety mechanism.

Processers such the GPU (e.g., GPU 104 of FIG. 1), may be configured with multiple sub-blocks. Each sub-block may handle a specific set of instructions or data processing. Each sub-block may have micro-idle cycles during which no further data/instructions are to be processed. During such micro-idle cycles, self-testing of the safety mechanism logic may be performed. Before the sub-block enters into a micro-idle cycle, the logic processing data may be captured. Then, when the micro-idle is asserted, the sub-block may enter into a self-test phase.

During the self-test phase, encoder output may be shorted with decoder input, along with the last processed data. That is, the input to the ECC decoder may be driven by the ECC encoder input data which may be concatenated with the encoder ECC output. The last processed data (e.g., the ECC Decoder output) may be provided to pattern generator logic. The pattern generator logic may capture last processed data. The pattern generator logic may generate a new pattern based on the captured last processed data. For instance, the pattern generator logic may invert a least significant bit (LSB) of the captured last processed data to form an intermediate pattern. Then, the pattern generator logic may perform a left shift operation on the intermediate pattern (e.g., by one position) to form the new pattern. The new pattern may be provided to an encoder, which, in turn, may generate a syndrome for newly provided data (e.g., the new pattern) from the pattern generator logic. The syndrome may be considered a product of a code word (e.g., the new pattern) and a parity check matrix transpose. The syndrome may be provided to a decoder along with newly generated data (e.g., the new pattern) from the pattern generator logic. A decoder may take the received syndrome and the new pattern, and determine if there is a syndrome match. Accordingly, when there is a fault in the encoder or decoder, an error may be reported because when the same data is given to the encoder and the decoder, the syndrome is expected to be the same.

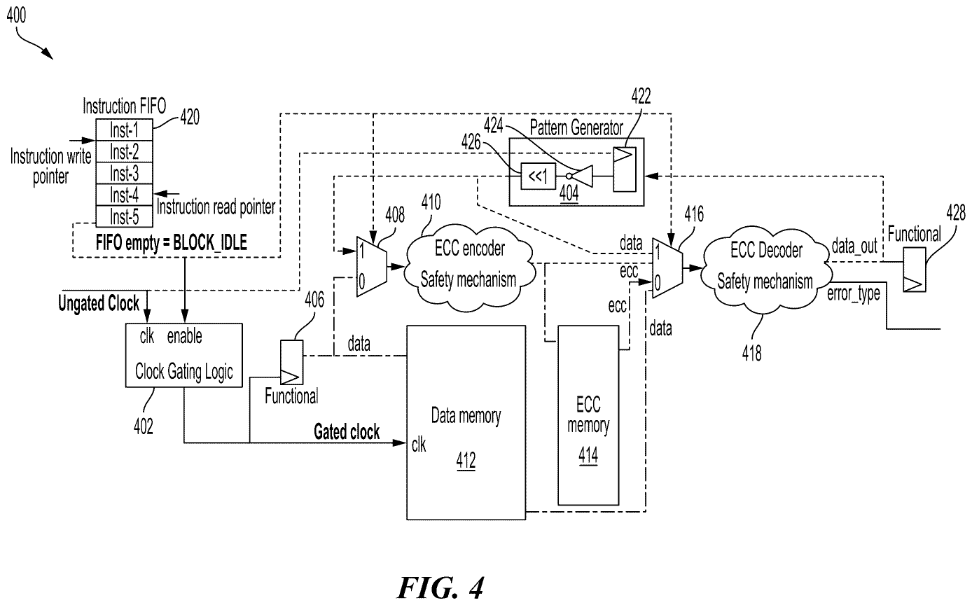

FIG. 4 is a block diagram illustrating an example architecture 400 for hardware-based periodic self-testing of safety mechanisms, in accordance with various aspects of the present disclosure. Referring to FIG. 4, the example architecture 400 includes clock gating logic 402 and a pattern generator 404. The example architecture 400 may also include a flip flop 406 and multiplexors (MUXs) 408, 416. The clock gating logic 402 may receive an ungated clock signal and may withhold or supply the clock signal to data memory 412 under the control of an instruction first in first out (FIFO) buffer 420. For instance, when the instruction FIFO buffer 420 is empty, a BLOCK_IDLE indication may trigger an enable signal to enable the clock gating logic 402. That is, when the instruction FIFO buffer 420 is idle, the clock gating logic 402 may supply a gated clock signal to the flip flop 406 and the data memory 412. As such, the data memory 412 may be restricted. That is, by gating the clock signal to the flip flop 406 and data memory 412, no data in the data memory 412 may be accessed.

The pattern generator 404 may include a flip flop 422 that stores the last (most recently) processed data. The pattern generator 404 may also include an inverter 424. The inverter 424 may invert the least significant bit of the last processed data. Then, a left shift operation (426) may generate a new test pattern. The new test pattern may be supplied as data to the MUX 416 and MUX 408. The BLOCK_IDLE indication may serve as a select an input of the MUX416 and MUX408. For example, when the BLOCK_IDLE indication is zero (FIFO buffer is not empty), input 0 of MUX 416 may be output by MUX416 and when BLOCK_IDLE indication is one (FIFO buffer is empty), the input 1 of MUX 416 may be output by MUX416.

Because the BLOCK_IDLE indication is one (FIFO buffer is empty) and the data of the data memory 412 is gated, the MUX 408 may select the new test pattern for output, and thus, may provide the new test pattern to an error correcting code (ECC) encoder safety mechanism 410. The ECC encoder safety mechanism 410 may generate a syndrome for the new test pattern. The syndrome may be stored in the ECC memory and may also be transmitted to the MUX 416. Because the BLOCK_IDLE indication is one (FIFO buffer is empty), the MUX 416 may output the input 1 of MUX 416, to provide the new test pattern as data and the syndrome to the ECC decoder safety mechanism 418. The ECC decoder safety mechanism 418 may decode the syndrome to recover a data value and compare the recovered data value to the new test pattern. When the recovered data matches the new test pattern, the self-test of the safety mechanism (e.g., 410 and/or 418) may be passed. The ECC decoder safety mechanism 418 may output the data (e.g., the new test pattern) which may be stored flip flop 422 (and functional flip flop 428) and used to generate subsequent test patterns for further testing.

On the other hand, when the recovered data value does not match the new test pattern, a fault may be detected in the safety mechanism (e.g., 410 and/or 418) and an interrupt may be reported. In some aspects, a warning message or reset command may be issued or another corrective action may be initiated. Accordingly, the self-testing may be repeated periodically or semi-periodically when the FIFO Buffer 420 is empty.

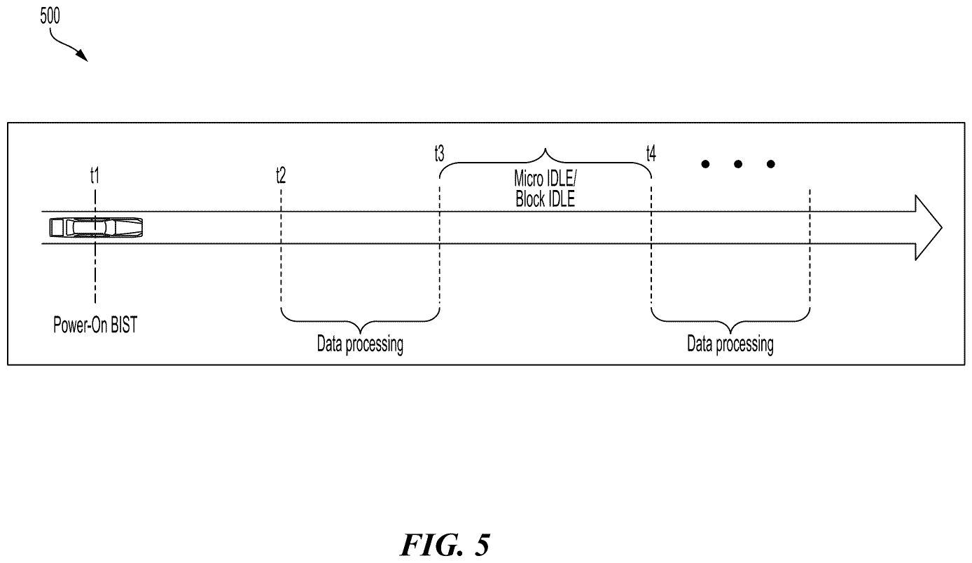

FIG. 5 is a diagram illustrating an example timeline 500 for periodic self-testing of safety mechanisms, in accordance with various aspects of the present disclosure. As shown in FIG. 5, at time t1, the safety mechanism may be tested at power-on via a built-in self-test (BIST). After the BIST passes, at time t2, data processing may be performed. Then, at time t3, when an idle period occurs (e.g., when the instruction FIFO buffer 420 shown in FIG. 4 is empty), hardware-based self-testing of the safety mechanism may be conducted. If the test passes, at time t4, the data processing may resume. If the hardware-based self-test has not passed, a corrective action may be initiated. Thereafter, the data processing may resume. Then, during subsequent idle periods, the safety mechanism may be tested again.

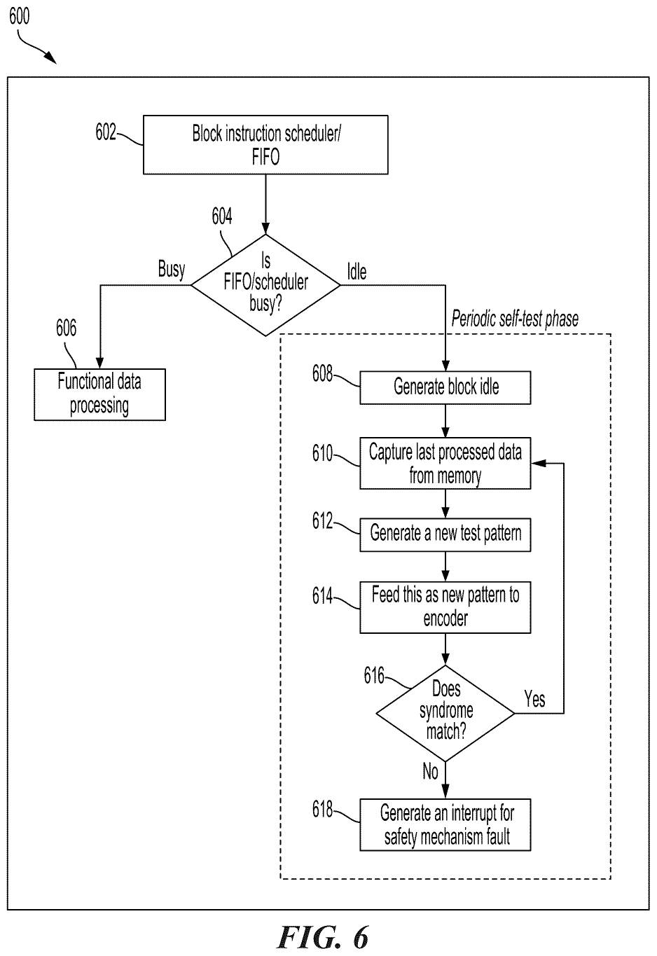

FIG. 6 is a flow diagram illustrating an example process 600 for hardware-based periodic self-testing of safety mechanisms, in accordance with various aspects of the present disclosure. Referring to FIG. 6, the example process 600 may be initiated after data processing has begun. In some aspects, the example process 600 may be initiated after the BIST has successfully completed.

At block 602, a block instruction scheduler (e.g., instruction FIFO buffer 420) may receive one or more instructions associated with data processing tasks. The block instruction scheduler may correspond to a block of a processor (e.g., GPU 104). Each processor may include one or more blocks. In an example, the block instruction scheduler may receive one or more instructions associated with an automotive application (e.g., braking systems, tire pressure monitoring systems, or self-driving vehicle systems) or other mission critical applications.

At block 604, the example process 600 may determine if the instruction scheduler is busy or idle. If the instruction scheduler (e.g., instruction FIFO buffer 420) includes an instruction to be processed, the example process 600 may determine that the instruction scheduler is busy. In some aspects, the example process 600 may determine that the instruction scheduler is busy if the instruction scheduler includes multiple instructions to be processed. When the instruction scheduler is determined to be busy, at block 606, the example process 600 may continue functional data processing of the instructions in the instruction scheduler.

On the other hand, when the instruction scheduler is determined to be idle (e.g., no instructions in the instruction FIFO buffer 420), at block 608, the example process 600 may generate a block idle. At block 610, the block idle may cause the pattern generator 404 to capture the last processed data from memory (e.g., in flip flop 422). At block 612, a new test pattern may be generated based on the last processed data. For example, the least significant bit of the last processed data may be inverted (e.g., using the NOT gate 424) to form an intermediate pattern. Then, a left shift (e.g., shift by one) may be applied (e.g., 426) to the intermediate pattern to produce the new test pattern.

At block 614, the new test pattern may be provided to an encoder of a safety mechanism (e.g., ECC encoder safety mechanism 410). The encoder may generate a syndrome based on the new test pattern. At block 616, the example process 600 may determine if the generated syndrome matches. If the syndrome matches, the example process 600 may return to block 610 to repeat the self-test. If, on the other hand the syndrome does not match, then at block 618, the example process 600 may generate an interrupt for a safety mechanism fault. In some aspects, other corrective measures may be initiated (e.g., a reset).

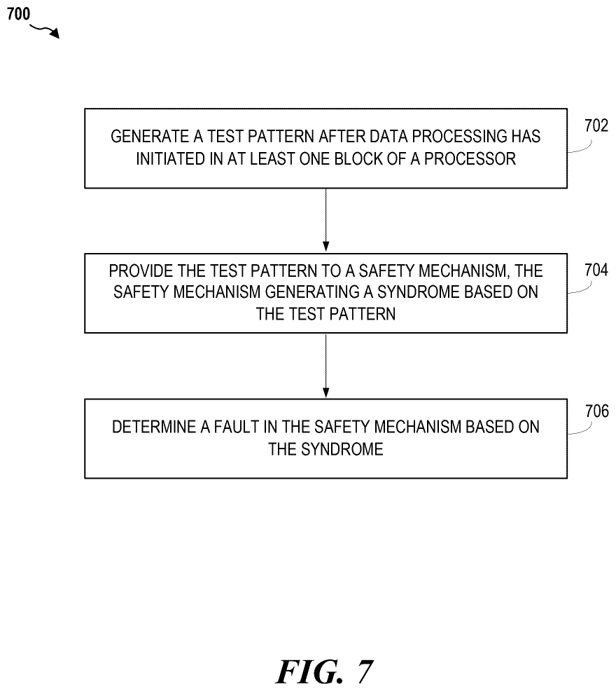

FIG. 7 is a flow chart illustrating an example process 700 performed, for example, by hardware logic such as the pattern generator 404, in accordance with various aspects of the present disclosure.

In some aspects, the process 700 may include generating a test pattern after data processing has initiated in at least one block of a processor (block 702). For example, as described with reference to FIG. 4, the pattern generator 404 may include a flip flop 422 that stores the last (most recently) processed data. The pattern generator 404 may also include an inverter 424. The inverter 424 may invert the least significant bit of the last processed data. Then, a left shift operation (426) may generate a new test pattern.

The process 700 may also include providing the test pattern to a safety mechanism, the safety mechanism generating a syndrome based on the test pattern (block 704). As described, for instance, with reference to FIG. 4, the new test pattern may be supplied as data to the MUX 416 and MUX 408. Because data of the data memory 412 is gated, the MUX 408 may select the new test pattern for output, and thus, may provide the new test pattern to an error correcting code (ECC) encoder safety mechanism 410.

The process 700 may further include determining a fault in the safety mechanism based on the syndrome (block 706). For example, as described with reference to FIG. 4, the ECC decoder safety mechanism 418 may decode the syndrome to recover a data value and compare the recovered data value to the new test pattern. When the recovered data matches the new test pattern, the self-test of the safety mechanism (e.g., 410 and/or 418) may be passed. On the other hand, when the recovered data value does not match the new test pattern, a fault may be detected in the safety mechanism (e.g., 410 and/or 418) and an interrupt may be reported. In some aspects, a warning message or reset command may be issued or another corrective action may be initiated.

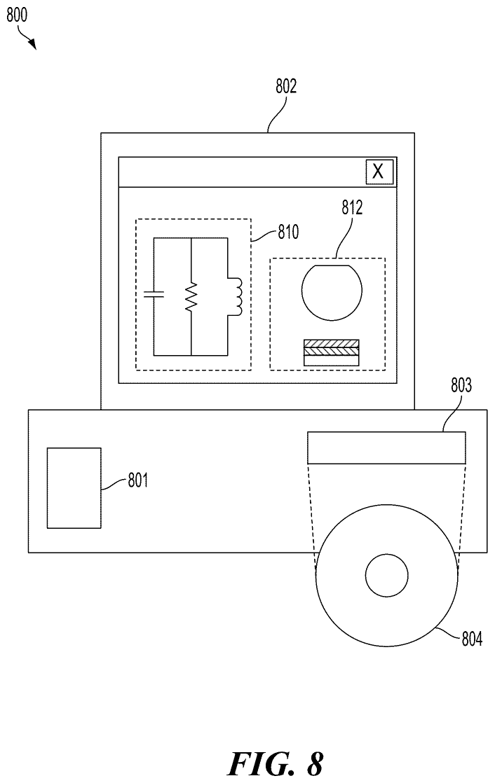

FIG. 8 is a block diagram illustrating a design workstation 800 used for circuit, layout, and logic design of a semiconductor component, such as the pattern generator 404, disclosed above. The design workstation 800 includes a hard disk 801 containing operating system software, support files, and design software such as Cadence or OrCAD. The design workstation 800 also includes a display 802 to facilitate design of a circuit 810 or a semiconductor component 812, such as the disclosed pattern generator 404. A storage medium 804 is provided for tangibly storing the design of the circuit 810 or the semiconductor component 812 (e.g., the pattern generator 404). The design of the circuit 810 or the semiconductor component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit 810 or the semiconductor component 812 by decreasing the number of processes for designing semiconductor wafers.

### Example Aspects

Aspect 1: An apparatus, comprising: at least one memory; and a safety mechanism for at least one block of a processor; logic for testing the safety mechanism, the logic being configured to: generate a test pattern after data processing has initiated in the at least one block of the processor; provide the test pattern to the safety mechanism, the safety mechanism generating a syndrome based on the test pattern; and determine a fault in the safety mechanism based on the syndrome.

Aspect 2: The apparatus of Aspect 1, in which the apparatus further includes an instruction scheduler for the at least one block of the processor and the logic is further configured to initiate the testing of the safety mechanism when the instruction scheduler for the at least one block of the processor is idle.

Aspect 3: The apparatus of Aspect 1 or 2, in which the at least one block of the processor is determined to be idle when the instruction scheduler has no instructions to be processed.

Aspect 4: The apparatus of any preceding Aspect, in which the logic is further configured to gate the at least one memory such that data of the at least one memory is not accessed.

Aspect 5: The apparatus of any preceding Aspect, in which the logic is further configured to: capture last processed data; invert a least significant bit of the last processed data to form an intermediate pattern; and perform a left shift operation on the intermediate pattern to generate the test pattern.

Aspect 6: The apparatus of any preceding Aspect, in which the safety mechanism comprises an error correction coding (ECC) safety mechanism.

Aspect 7: The apparatus of any preceding Aspect, in which the logic is further configured to initiate at least one corrective action in response to the fault.

Aspect 8: A method, comprising: generating a test pattern after data processing has initiated in at least one block of a processor; providing the test pattern to a safety mechanism, the safety mechanism generating a syndrome based on the test pattern; and determining a fault in the safety mechanism based on the syndrome.

Aspect 9: The method of Aspect 8, further comprising initiating testing of the safety mechanism when an instruction scheduler for the at least one block of the processor is idle.

Aspect 10: The method of Aspect 8 or 9, further comprising determining the at least one block of the processor is idle when the instruction scheduler has no instructions to be processed.

Aspect 11: The method of any of Aspects 8-10, further comprising gating a memory such that data stored in the memory is not accessed.

Aspect 12: The method of any of Aspects 8-11, further comprising:
capturing last processed data; inverting a least significant bit of the last processed data to form an intermediate pattern; and performing a left shift operation on the intermediate pattern to generate the test pattern.

Aspect 13: The method of any of Aspects 8-12, in which the safety mechanism comprises an error correction coding (ECC) safety mechanism.

Aspect 14: The method of any of Aspects 8-13, further comprising initiating at least one corrective action in response to the fault.

Aspect 15: An apparatus, comprising: means for generating a test pattern after data processing has initiated in at least one block of a processor; means for providing the test pattern to a safety mechanism, the safety mechanism generating a syndrome based on the test pattern; and means for determining a fault in the safety mechanism based on the syndrome.

Aspect 16: The apparatus of Aspect 15, further comprising means for initiating testing of the safety mechanism when an instruction scheduler for the at least one block of the processor is idle.

Aspect 17: The apparatus of Aspect 15 or 16, further comprising means for determining the at least one block of the processor is idle when the instruction scheduler has no instructions to be processed.

Aspect 18: The apparatus of any of Aspects 15-17, further comprising means for gating a memory such that data stored in the memory is not accessed.

Aspect 19: The apparatus of any of Aspects 15-18, further comprising:
means for capturing last processed data; means for inverting a least significant bit of the last processed data to form an intermediate pattern; and means for performing a left shift operation on the intermediate pattern to generate the test pattern.

Aspect 20: The apparatus of any of Aspects 15-19, further comprising means for initiating at least one corrective action in response to the fault.

The various operations of methods described above may be performed by any suitable means capable of performing the corresponding functions. The means may include various hardware and/or software component(s) and/or module(s), including, but not limited to, a circuit, an application specific integrated circuit (ASIC), or processor. Generally, where there are operations illustrated in the figures, those operations may have corresponding counterpart means-plus-function components with similar numbering.

As used, the term “determining” encompasses a wide variety of actions. For example, “determining” may include calculating, computing, processing, deriving, investigating, looking up (e.g., looking up in a table, a database, or another data structure), ascertaining and the like. Additionally, “determining” may include receiving (e.g., receiving information), accessing (e.g., accessing data in a memory) and the like. Furthermore, “determining” may include resolving, selecting, choosing, establishing, and the like.

As used, a phrase referring to “at least one of” a list of items refers to any combination of those items, including single members. As an example, “at least one of: a, b, or c” is intended to cover: a, b, c, a-b, a-c, b-c, and a-b-c.

The various illustrative logical blocks, modules and circuits described in connection with the present disclosure may be implemented or performed with a general-purpose processor, a digital signal processor (DSP), an application specific integrated circuit (ASIC), a field programmable gate array signal (FPGA) or other programmable logic device (PLD), discrete gate or transistor logic, discrete hardware components or any combination thereof designed to perform the functions described. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in any form of storage medium that is known in the art. Some examples of storage media that may be used include random access memory (RAM), read-only memory (ROM), flash memory, erasable programmable read-only memory (EPROM), electrically erasable programmable read-only memory (EEPROM), registers, a hard disk, a removable disk, a CD-ROM and so forth. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a device. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement signal processing functions. For certain aspects, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processor may be responsible for managing the bus and general processing, including the execution of software stored on the machine-readable media. The processor may be implemented with one or more general-purpose and/or special-purpose processors. Examples include microprocessors, microcontrollers, DSP processors, and other circuitry that can execute software. Software shall be construed broadly to mean instructions, data, or any combination thereof, whether referred to as software, firmware, middleware, microcode, hardware description language, or otherwise. Machine-readable media may include, by way of example, random access memory (RAM), flash memory, read-only memory (ROM), programmable read-only memory (PROM), erasable programmable read-only memory (EPROM), electrically erasable programmable Read-only memory (EEPROM), registers, magnetic disks, optical disks, hard drives, or any other suitable storage medium, or any combination thereof. The machine-readable media may be embodied in a computer-program product. The computer-program product may comprise packaging materials.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the device, all which may be accessed by the processor through the bus interface. Alternatively, or in addition, the machine-readable media, or any portion thereof, may be integrated into the processor, such as the case may be with cache and/or general register files. Although the various components discussed may be described as having a specific location, such as a local component, they may also be configured in various ways, such as certain components being configured as part of a distributed computing system.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may comprise one or more neuromorphic processors for implementing the neuron models and models of neural systems described. As another alternative, the processing system may be implemented with an application specific integrated circuit (ASIC) with the processor, the bus interface, the user interface, supporting circuitry, and at least a portion of the machine-readable media integrated into a single chip, or with one or more field programmable gate arrays (FPGAs), programmable logic devices (PLDs), controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

The machine-readable media may comprise a number of software modules. The software modules include instructions that, when executed by the processor, cause the processing system to perform various functions. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a general register file for execution by the processor. When referring to the functionality of a software module below, it will be understood that such functionality is implemented by the processor when executing instructions from that software module. Furthermore, it should be appreciated that aspects of the present disclosure result in improvements to the functioning of the processor, computer, machine, or other system implementing such aspects.

If implemented in software, the functions may be stored or transmitted over as one or more instructions or code on a computer-readable medium. Computer-readable media include both computer storage media and communication media including any medium that facilitates transfer of a computer program from one place to another. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Additionally, any connection is properly termed a computer-readable medium. For example, if the software is transmitted from a website, server, or other remote source using a coaxial cable, fiber optic cable, twisted pair, digital subscriber line (DSL), or wireless technologies such as infrared (IR), radio, and microwave, then the coaxial cable, fiber optic cable, twisted pair, DSL, or wireless technologies such as infrared, radio, and microwave are included in the definition of medium. Disk and disc, as used, include compact disc (CD), laser disc, optical disc, digital versatile disc (DVD), floppy disk, and Blu-ray® disc where disks usually reproduce data magnetically, while discs reproduce data optically with lasers. Thus, in some aspects, computer-readable media may comprise non-transitory computer-readable media (e.g., tangible media). In addition, for other aspects computer-readable media may comprise transitory computer-readable media (e.g., a signal). Combinations of the above should also be included within the scope of computer-readable media.

Thus, certain aspects may comprise a computer program product for performing the operations presented. For example, such a computer program product may comprise a computer-readable medium having instructions stored (and/or encoded) thereon, the instructions being executable by one or more processors to perform the operations described. For certain aspects, the computer program product may include packaging material.

Further, it should be appreciated that modules and/or other appropriate means for performing the methods and techniques described can be downloaded and/or otherwise obtained by a user terminal and/or base station as applicable. For example, such a device can be coupled to a server to facilitate the transfer of means for performing the methods described. Alternatively, various methods described can be provided via storage means (e.g., RAM, ROM, a physical storage medium such as a compact disc (CD) or floppy disk, etc.), such that a user terminal and/or base station can obtain the various methods upon coupling or providing the storage means to the device. Moreover, any other suitable technique for providing the methods and techniques described to a device can be utilized.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. An apparatus, comprising:
at least one memory;
a safety mechanism for at least one block of a processor; and
logic for testing the safety mechanism, the logic being configured to:
generate a test pattern after data processing has initiated in the at least one block of the processor;
provide the test pattern to the safety mechanism, the safety mechanism generating a syndrome based on the test pattern; and
determine a fault in the safety mechanism based on the syndrome.

2. The apparatus of claim 1, in which the apparatus further includes an instruction scheduler for the at least one block of the processor and the logic is further configured to initiate the testing of the safety mechanism when the instruction scheduler for the at least one block of the processor is idle.

3. The apparatus of claim 2, in which the at least one block of the processor is determined to be idle when the instruction scheduler has no instructions to be processed.

4. The apparatus of claim 1, in which the logic is further configured to gate the at least one memory such that data of the at least one memory is not accessed.

5. The apparatus of claim 1, in which the logic is further configured to:
capture last processed data;
invert a least significant bit of the last processed data to form an intermediate pattern; and
perform a left shift operation on the intermediate pattern to generate the test pattern.

6. The apparatus of claim 1, in which the safety mechanism comprises an error correction coding (ECC) safety mechanism.

7. The apparatus of claim 1, in which the logic is further configured to initiate at least one corrective action in response to the fault.

8. A method, comprising:
generating a test pattern after data processing has initiated in at least one block of a processor;
providing the test pattern to a safety mechanism, the safety mechanism generating a syndrome based on the test pattern; and
determining a fault in the safety mechanism based on the syndrome.

9. The method of claim 8, further comprising initiating testing of the safety mechanism when an instruction scheduler for the at least one block of the processor is idle.

10. The method of claim 9, further comprising determining the at least one block of the processor is idle when the instruction scheduler has no instructions to be processed.

11. The method of claim 8, further comprising gating a memory such that data stored in the memory is not accessed.

12. The method of claim 8, further comprising:
capturing last processed data;
inverting a least significant bit of the last processed data to form an intermediate pattern; and
performing a left shift operation on the intermediate pattern to generate the test pattern.

13. The method of claim 8, in which the safety mechanism comprises an error correction coding (ECC) safety mechanism.

14. The method of claim 8, further comprising initiating at least one corrective action in response to the fault.

15. An apparatus, comprising:
means for generating a test pattern after data processing has initiated in at least one block of a processor;
means for providing the test pattern to a safety mechanism, the safety mechanism generating a syndrome based on the test pattern; and
means for determining a fault in the safety mechanism based on the syndrome.

16. The apparatus of claim 15, further comprising means for initiating testing of the safety mechanism when an instruction scheduler for the at least one block of the processor is idle.

17. The apparatus of claim 16, further comprising means for determining the at least one block of the processor is idle when the instruction scheduler has no instructions to be processed.

18. The apparatus of claim 15, further comprising means for gating a memory such that data stored in the memory is not accessed.

19. The apparatus of claim 15, further comprising:
means for capturing last processed data;
means for inverting a least significant bit of the last processed data to form an intermediate pattern; and
means for performing a left shift operation on the intermediate pattern to generate the test pattern.

20. The apparatus of claim 15, further comprising means for initiating at least one corrective action in response to the fault.
